(19) United States
(12) Patent Application Publication
(10) Pub. No.: US 2026/0188938 A1
(43) Pub. Date: Jul. 2, 2026

(54) CONNECTOR

(71) Applicant: SUMITOMO WIRING SYSTEMS, LTD., Mie (JP)

(72) Inventors: Koyo TAKASAKI, Mie (JP); Hiroto SAKAI, Mie (JP)

(21) Appl. No.: 18/868,167

(22) PCT Filed: May 9, 2023
(86) PCT No.: PCT/JP2023/017433

§ 371 Date: Nov. 22, 2024

(30) Foreign Application Priority Data
May 24, 2022 (JP) 2022-084629

(51) Int. Cl. H01R 13/52; H01R 12/70; H01R 12/72; H01R 13/74; H05K 5/06

(52) U.S. Cl. CPC H01R 13/5202; H01R 12/7023; H01R 12/724; H01R 13/74; H05K 5/069

(57) ABSTRACT

It is aimed to provide a connector capable of hindering the intrusion of an external matter to a back side of a receptacle and ensuring strength on an opening side of a receptacle. A connector (10) includes a receptacle (16), into which a mating connector (P) is fittable. If an opening side of the receptacle (16) is a front side and a side opposite to the opening side is a back side, the receptacle (16) includes a flange portion (16A) formed into a flange shape on an outer periphery of an end edge on the front side, a second flange portion (16B) arranged to face the flange portion (16A) from the back side, and a groove portion (16C) formed between the second flange portion (16B) and the flange portion (16A), a plate-like case (80) being fit into the groove portion (16C).

### TECHNICAL FIELD

The present disclosure relates to a connector.

### BACKGROUND

Patent Document 1 and 2 disclose a configuration in which a receptacle formed into a rectangular tube by four wall portions is sandwiched in a vertical direction by an upper case and a lower case. This receptacle is formed with a recess extending in a circumferential direction (i.e. in the four wall portions) and recessed inward, and the intrusion of an external matter into inside is restricted by inserting and fitting protrusions provided on the upper and lower cases into this recess.

### PRIOR ART DOCUMENT

### Patent Document

Patent Document 1: JP 2009-070855 A
Patent Document 2: JP 2009-123558 A

### SUMMARY OF THE INVENTION

### Problems to be Solved

The receptacle of a connector of Patent Documents 1 and 2 is arranged to project out from the upper and lower cases. Thus, there is a concern that an external matter moves toward the upper and lower cases along the outer surface of the receptacle and intrudes into the case. Further, with a mating connector fit in the receptacle, there is a concern that the front end (end edge on an opening side) of the receptacle is expanded and deformed when a wire pulled out from the mating connector vibrates or is pulled up.

Accordingly, the present disclosure aims to provide a connector capable of hindering the intrusion of an external matter and ensuring strength on an opening side of a receptacle.

### Means to Solve the Problem

The present disclosure is directed to a connector with a receptacle, a mating connector being fittable into the receptacle, if an opening side of the receptacle is a front side and a side opposite to the opening side is a back side, the receptacle including a flange portion formed into a flange shape on an outer periphery of an end edge on the front side, a facing portion arranged to face the flange portion from the back side, and a groove portion formed between the facing portion and the flange portion, a plate-like case being fit into the groove portion.

### Effect of the Invention

According to the present disclosure, it is possible to hinder the intrusion of an external matter to a back side of a receptacle and ensure strength on an opening side of the receptacle.

### BRIEF DESCRIPTION OF THE DRAWINGS

FIG. 1 is a perspective view of a connector according to one embodiment.

FIG. 2 is a front view of the connector having a case mounted thereon.

FIG. 3 is a back view of the connector.

FIG. 4 is a side view of the connector having the case mounted thereon.

FIG. 5 is a side view of a connector of another embodiment.

### DETAILED DESCRIPTION TO EXECUTE THE INVENTION

### Description of Embodiments of Present Disclosure

First, embodiments of the present disclosure are listed and described.

(1) The connector of the present disclosure is provided with a receptacle, a mating connector being fittable into the receptacle. If an opening side of the receptacle is a front side and a side opposite to the opening side is a back side, the receptacle including a flange portion, a facing portion and a groove portion. The flange portion is formed into a flange shape on an outer periphery of an end edge on the front side. The facing portion is arranged to face the flange portion from the back side. The groove portion is formed between the facing portion and the flange portion, a plate-like case being fit into the groove portion.

According to this configuration, by fitting the plate-like case into the groove portion, the case can be fit between the flange portion and the facing portion in a concave and convex manner. As a result, the intrusion of an external matter into the case through a gap between the flange portion and the facing portion can be hindered. Particularly, since the flange portion is formed on the end edge on the front side (opening end) of the receptacle, the intrusion of the external matter can be quickly hindered. Further, the end edge on the front side (opening end) of the receptacle is reinforced by the flange portion and, in addition, reinforced also by the case fit in the groove portion. As a result, when a wire pulled out from the mating connector fit into the receptacle vibrates or is pulled up, the deformation of the end edge on the front side of the receptacle can be suppressed.

(2) Preferably, the facing portion is a second flange portion formed into a flange shape behind the end edge on the front side on the outer periphery of the receptacle.

According to this configuration, since a depth of the groove portion can be increased, the plate-like case can be more deeply fit into the groove portion in a concave and convex manner and a chance of an external matter to intrude into the case can be reduced more.

(3) Preferably, one surface of the receptacle is a mounting surface to be mounted on a circuit board, out of four surfaces of the outer periphery having a rectangular tube shape, and the flange portion and the second flange portion are formed over three surfaces including a pair of side surfaces and an end surface located on a side opposite to the mounting surface except the mounting surface, out of the four surfaces of the outer periphery.

According to this configuration, the intrusion of an external matter into the case along any one of the three surfaces of the outer periphery can be hindered. Even if an external matter is intruding into the case along the mounting surface, such an intrusion can be hindered by the contact of the external matter with the front end of the circuit board.

(4) Preferably, the flange portion and the second flange portion include side flange portions and second side flange portions on the respective side surfaces, and the side flange portions and the second side flange portions are shaped to increase an outward projecting amount from the side surface from the end surface side toward the mounting surface side.

If the flange portion and the second flange portion are formed over the three surfaces of the outer periphery of the receptacle, the case includes an opening portion in the form of a rectangular recess (hereinafter, also merely referred to as an opening portion) to be fit to the three surfaces of the outer periphery of the receptacle. Here, an opening side of the opening portion of the case is preferably set to be wider than an inner side. According to this configuration, an end part on the opening side of the opening portion in the case can be sandwiched by the side flange portions and the second side flange portions. As a result, a concave-convex structure can be realized by arranging the end part on the opening side of the opening portion between the side flange portions and the second side flange portions.

(5) Preferably, the side surface of the receptacle includes a press-fit portion, a fixing member for fixing the receptacle to the circuit board being press-fit into the press-fit portion, and a front end of the press-fit portion is integrally coupled to the second flange portion.

According to this configuration, since the press-fit portion is reinforced by the second flange portion, the fixing member can be properly held. Further, since the second flange portion is reinforced by the press-fit portion, the deformation of the second flange portion due to contact with the case can be prevented.

(6) Preferably, the case is in contact with at least one of a back surface of the flange portion and a front surface of the second flange portion.

According to this configuration, the intrusion of an external matter into the case can be more reliably prevented.

### Details of Embodiment of Present Disclosure

### Embodiment

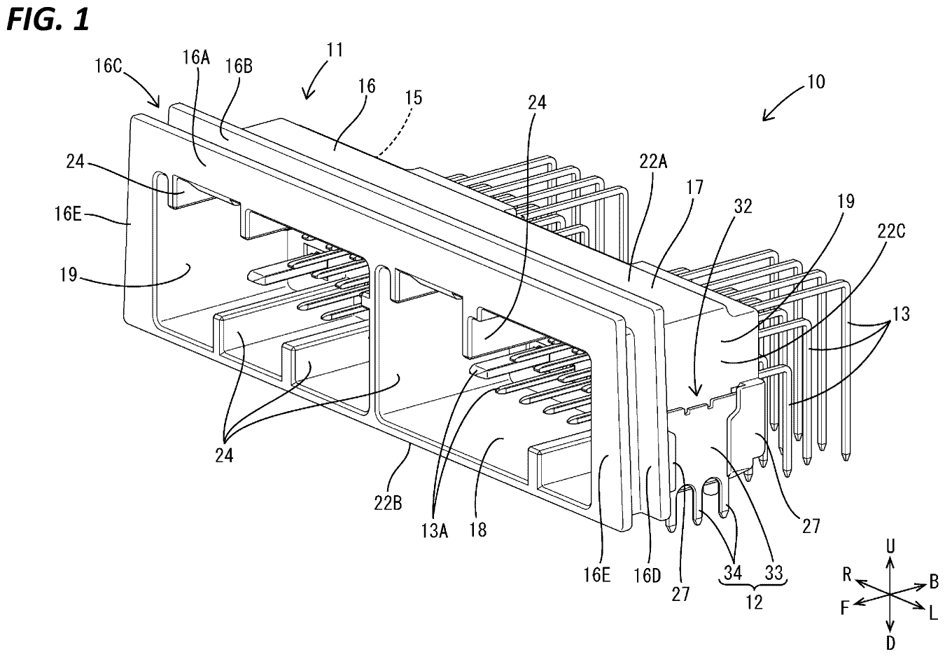

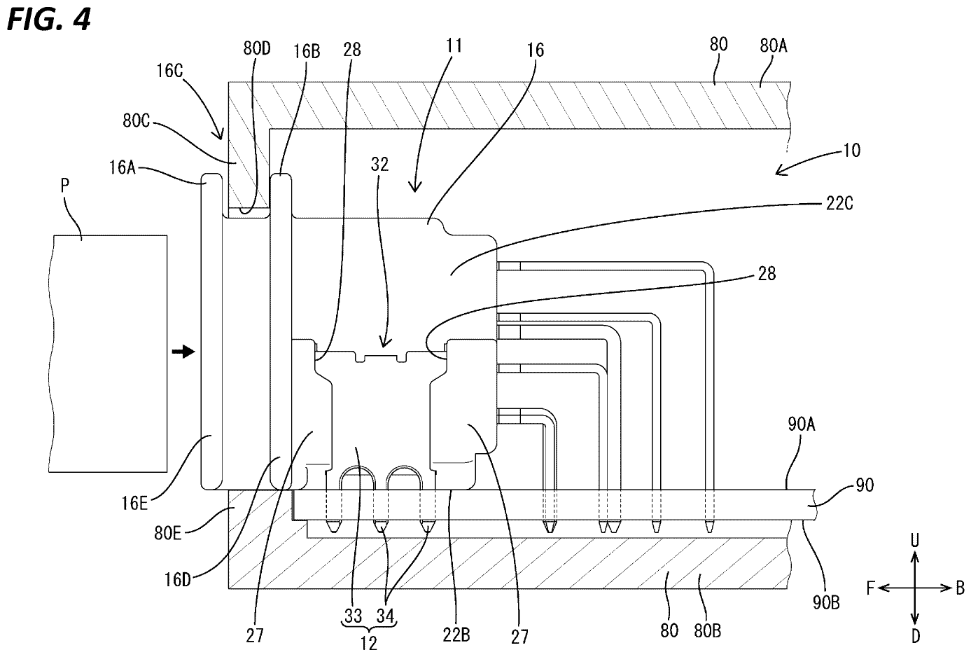

A connector 10 to be disposed on a circuit board 90 is described with reference to FIGS. 1 to 4. In figures, a “front side”, a “back side”, an “upper side”, a “lower side”, a “right side” and a “left side” are respectively represented by “F”, “B”, “U”, “D”, “R” and “L”. In the following description, a direction of connecting a mating connector P to the connector 10 is defined as a connection direction (front-back direction) (see FIG. 4). In this embodiment, a lateral direction is equivalent to a width direction.

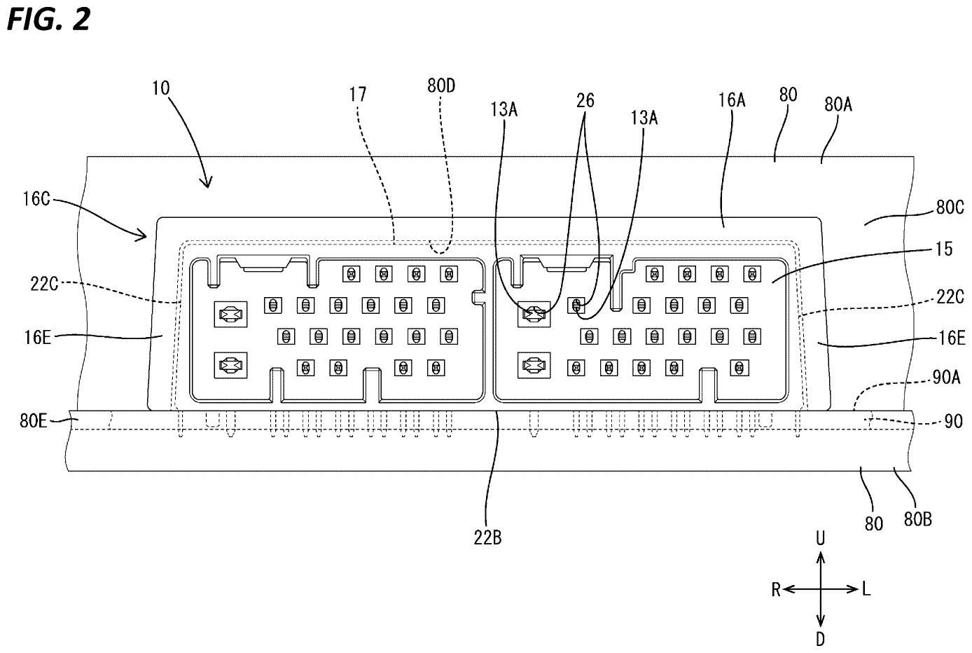

The connector 10 according to this embodiment is provided with a housing 11, fixing members 12 and a plurality of terminal fittings 13 (see FIG. 1). The connector 10 is covered by a case 80 while being mounted on the circuit board 90 except a front side, which is a side to be connected to the mating connector P (see FIG. 2).

### [Configuration of Connector]

The housing 11 is made of synthetic resin. As shown in FIG. 1, the housing 11 includes a wall portion 15 elongated in the lateral direction and arranged with a plate thickness direction oriented in the front-back direction and a receptacle 16 in the form of a rectangular tube projecting forward from the outer edge of the wall portion 15. The mating connector P is fittable into the receptacle 16 (see FIG. 4). An opening side of the receptacle 16 is located on a front side, and a side (side of the wall portion 15) opposite to the opening side of the receptacle 16 is a back side. The receptacle 16 includes an upper wall 17 and a lower wall 18 arranged and paired in the vertical direction and side walls 19 arranged and paired in the lateral direction. Each of the upper and lower walls 17, 18 is provided with a plurality of inner walls 24 projecting into the receptacle 16 on the inner surface thereof. The wall portion 15 includes a plurality of through holes 26 penetrating in the plate thickness direction (front-back direction) (see FIG. 2). The terminal fitting 13 is mounted into each through hole 26 by being press-fit or inserted from behind.

The upper surface of the upper wall 17 is an end surface 22A. The lower surface of the lower wall 18 is a mounting surface 22B (see FIGS. 2 and 4). The mounting surface 22B is a surface facing and contacting a surface 90A of the circuit board 90 when the connector 10 is mounted on the circuit board 90.

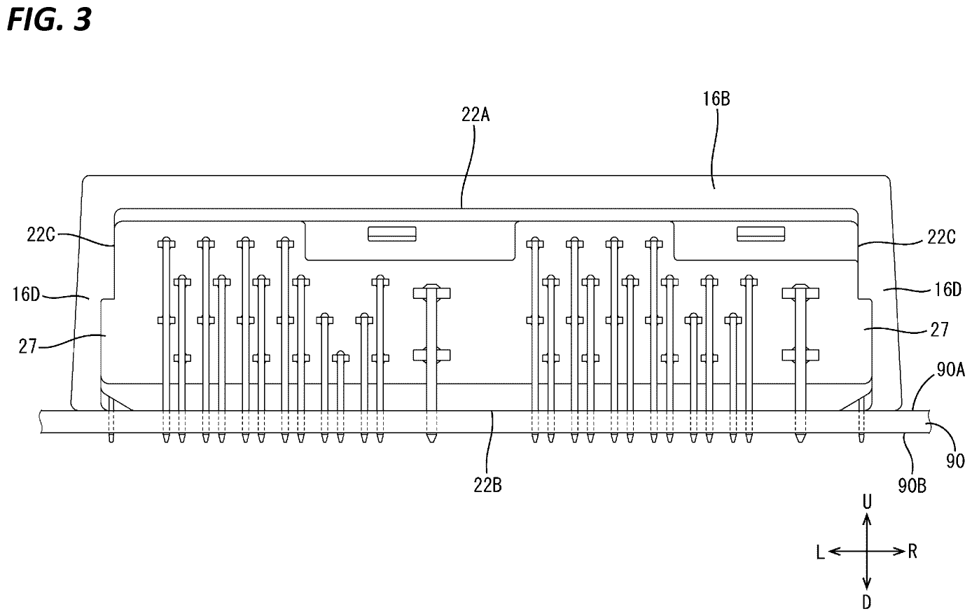

Each side wall 19 has a side surface 22C (see FIG. 3). Each side surface 22C is a surface facing outward in the lateral direction. Each side surface 22C is provided with press-fit portions 27 projecting outward in the width direction. The press-fit portions 27 are provided separately on front and back sides on one side surface 22C. Slit-like grooves 28 are formed by cutting inner surfaces facing each other in the front-back direction in the respective press-fit portions 27 on the front and back sides on one side surface 22C (see FIG. 4). The fixing member 12 to be described later is press-fit and held in the grooves 28 from above.

The receptacle 16 further includes a flange portion 16A, a second flange portion 16B, which is a facing portion, and a groove portion 16C. The flange portion 16A is formed into a flange shape to protrude on the outer periphery of an end edge on the front side of the receptacle 16. The flange portion 16A includes side flange portions 16E. Each of the flange portion 16A and the side flange portions 16E is in the form of one flat plate. The flange portion 16A and the side flange portions 16E are formed over three surfaces including a pair of the side surfaces 22C and the end surface 22A located on a side opposite to the mounting surface 22B except the mounting surface 22B, out of four surfaces of the outer periphery of the receptacle 16. The side flange portion 16E is provided to project outward in the lateral direction on each side surface 22C. The front surface of the flange portion 16A defines the opening surface of the receptacle 16.

The second flange portion 16B is arranged behind the flange portion 16A to face and be separated from the flange portion 16A from the back side. The second flange portion 16B is formed into a flange shape to protrude behind the end edge on the front side on the outer periphery of the receptacle 16. The second flange portion 16B includes second side flange portions 16D. The second flange portion 16B and the second side flange portions 16D are in the form of one flat plate. The second flange portion 16B and the second side flange portions 16E are formed over the three surfaces including the pair of the side surfaces 22C and the end surface 22A located on the side opposite to the mounting surface 22B except the mounting surface 22B, out of the four surfaces of the outer periphery of the receptacle 16 (see FIG. 3). The second side flange portion 16D is provided to project outward in the lateral direction on each side surface 22C (see FIG. 3).

The side flange portions 16E and the second side flange portions 16D are formed to gradually increase a laterally outward projecting amount from the side of the end surface 22A toward the side of the mounting surface 22B (see FIGS. 2 and 3).

The groove portion 16C is formed between the flange portion 16A and the second flange portion 16B. The groove portion 16C is a part relatively recessed from the tips of the flange portion 16A and the second flange portion 16B in a projecting direction.

The fixing member 12 is a plate member made of metal and mounted into the respective grooves 28 of the housing 11. The fixing member 12 includes a housing mounting portion 33 to be arranged along the side surface 22C with plate surfaces facing in the width direction and board fixing portions 34 extending downward like a comb from the lower end of the housing mounting portion 33.

Front and back end parts of the housing mounting portion 33 are respectively fit into the grooves 28 formed in the press-fit portions 27 (see FIG. 4). In this way, the fixing member 12 is held on the receptacle 16 of the housing 11. The board fixing portions 34 are inserted into unillustrated insertion holes formed in the circuit board 90 and fixed to the circuit board 90 by being soldered. The receptacle 16 is fixed to the circuit board 90 via the fixing members 12.

The plurality of terminal fittings 13 are male terminal fittings and formed, such as by stamping and bending an electrically conductive metal plate. Each terminal fitting 13 is inserted into the through hole 26 from behind and held through the through hole 26. A tab 13A is provided on a tip (front end part) of each terminal fitting 13. Each tab 13A is accommodated in the receptacle 16. With the connector 10 connected to the mating connector P, each tab 13A is connected to an unillustrated mating terminal provided in the mating connector P. A back end part of each terminal fitting 13 is inserted into an insertion hole formed in the circuit board 90 and connected to an underside 90B of the circuit board 90 by being soldered.

As shown in FIG. 4, the connector 10 formed in this way is so mounted that the mounting surface 22B faces the surface 90A of the circuit board 90. The connector 10 is so arranged that the flange portion 16A and the second flange portion 16B project further forward than the front end edge of the circuit board 90.

### [Concerning Case]

In the case of this embodiment, the case 80 is made of die-casting. As shown in FIG. 2, the case 80 includes an upper case 80A and a lower case 80B. The upper and lower cases 80A, 80B sandwich the circuit board 90 having the connector 10 mounted thereon in the vertical direction. A flat plate-like front wall 80C of the upper case 80A is cut in conformity with the outer shape of the groove portion 16C of the connector 10 to form an opening portion 80D in the form of a rectangular recess. A plate thickness direction of the front wall 80C of the upper case 80A is oriented in the front-back direction. Considering that the upper case 80A is made of die-casting, the opening portion 80D is formed to gradually increase a dimension in the lateral direction from an inner part (upper part) of the upper case 80A toward the circuit board 90 (lower side). In this way, the mold releasability of the case 80 is improved. The opening portion 80D has a trapezoidal shape in a front view.

The upper case 80A is mounted on the surface 90A of the circuit board 90 to cover the connector 10. As shown in FIG. 4, the front wall 80C is fit into the groove portion 16C between the back surface of the flange portion 16A and the front surface of the second flange portion 16B. A plate thickness of the front wall 80C is smaller than a dimension between the back surface of the flange portion 16A and the front surface of the second flange portion 16B. In the case of this embodiment, the back surface of the front wall 80C contacts the front surface of the second flange portion 16B from front. In this way, the case 80 is positioned in the front-back direction with respect to the connector 10. Along with this, the intrusion of an external matter into the case 80 from outside by way of the second flange portion 16B can be reliably prevented. In this way, the back surface of the flange portion 16A, the second flange portion 16B and the front wall 80C are fit in a concave and convex manner. A front end part of the housing 11 is facing forward of the case 80 through the opening portion 80D formed in the front wall 80C of the case 80.

As shown in FIGS. 2 and 3, the side flange portions 16E and the second side flange portions 16D are formed to gradually increase a laterally outward projecting amount from the side of the end surface 22A toward the side of the mounting surface 22B. Thus, even if the opening portion 80D is formed to gradually increase a dimension in the lateral direction from the inner part (upper part) of the case 80 toward the side of the circuit board 90 (lower side), the side flange portions 16E and the second side flange portions 16D and both sides in the lateral direction of the opening portion 80D are reliably fit in a concave and convex manner. Further, the inner surface (i.e. side surface 22C) of the groove portion 16C formed on the side walls 19 is formed to gradually expand more outward in the lateral direction from the side of the side surface 22A toward the side of the mounting surface 22B similarly to the side flange portions 16E and the second side flange portions 16D (see FIG. 2). In this way, the inner surface of the groove portion 16C on the side walls 19 can extend along the both side edges in the lateral direction of the opening portion 80D and gaps formed between the upper case 80A and the housing 11 can be reduced.

The lower case 80B is mounted on the underside 90B of the circuit board 90. The lower case 80B is arranged on a side opposite to the upper case 80A across the circuit board 90. A rib 80E long in the lateral direction and projecting upward is provided on a front end part of the lower case 80B (see FIGS. 2 and 4). The rib 80E is arranged to cover the front end of the circuit board 90 from front and the tip thereof is arranged to face the mounting surface 22B of the receptacle 16 (see FIG. 4). The tip of the rib 80E is in contact with the lower end of the front wall 80C on sides laterally outward of the opening portion 80D (see FIG. 2).

In the case of this embodiment, the mounting surface 22B and the surface 90A of the circuit board 90 are in contact and an interval therebetween is set to be less than 1.0 mm. The back surface of the front wall 80C is in contact with the front surface of the second flange portion 16B from front. Thus, in the case of this embodiment, the entrance of an external matter having a diameter of 1.0 mm or more into the case 80 can be prevented.

Next, functions of this embodiment are described.

The connector 10 is provided with the receptacle 16, into which the mating connector P is fittable. If the opening side of the receptacle 16 is the front side and the side opposite to the opening side is the back side, the receptacle 16 includes the flange portion 16A, the second flange portion 16B and the groove portion 16C. The flange portion 16A is formed into a flange shape on the outer periphery of the end edge on the front side. The second flange portion 16B is arranged to face the flange portion 16A from the back side. The groove portion 16C is formed between the second flange portion 16B and the flange portion 16A, and the front wall 80C of the plate-like case 80 is fit into the groove portion 16C. According to this configuration, by fitting the plate-like case 80 into the groove portion 16C, the case 80 can be fit between the flange portion 16A and the second flange portion 16B in a concave and convex manner. As a result, the intrusion of an external matter into the case 80 through a gap between the flange portion 16A and the second flange portion 16B can be hindered. Particularly, since the flange portion 16A is formed on the end edge on the front side (opening end) of the receptacle 16, the intrusion of an external matter can be quickly hindered. Further, the end edge on the front side (opening end) of the receptacle 16 is reinforced by the flange portion 16A and, in addition, reinforced also by the case 80 fit into the groove portion 16C. As a result, when wires pulled out from the mating connector P fit inside the receptacle 16 vibrate or are pulled up, the deformation of the end edge on the front side of the receptacle 16 can be suppressed.

The facing portion is the second flange portion 16B formed into a flange shape behind the end edge on the front side on the outer periphery of the receptacle 16. According to this configuration, since a depth of the groove portion 16C can be increased, the plate-like case 80 can be more deeply fit into the groove portion 16C in a concave and convex manner and a chance of an external matter to intrude into the case 80 can be reduced more.

Out of the four surfaces of the outer periphery of the receptacle 16 in the form of a rectangular tube, one surface is the mounting surface 22B to be mounted on the circuit board 90. The flange portion 16A and the second flange portion 16B are formed over the three surfaces including the pair of side surfaces 22C and the end surface 22A located on the side opposite to the mounting surface 22B except the mounting surface 22B, out of the four surfaces of the outer periphery. According to this configuration, the intrusion of an external matter into the case 80 along any one of the three surfaces of the outer periphery can be hindered. Even if an external matter is intruding into the case 80 along the mounting surface 22B, such an intrusion can be hindered by the contact of the external matter with the front end of the circuit board 90.

The flange portion 16A and the second flange portion 16B include the side flange portions 16E and the second side flange portions 16D on the respective side surfaces 22C. The side flange portions 16E and the second side flange portions 16D are shaped to increase the outward projecting amount from the side surfaces 22C from the side of the end surface 22A toward the side of the mounting surface 22B. If the flange portion 16A and the second flange portion 16B are formed over the three surfaces of the outer periphery of the receptacle 16, the case 80 includes the opening portion 80D to be fit to the three surfaces of the outer periphery of the receptacle 16. Here, the opening side of the opening portion 80D of the case 80 is preferably set to be wider than the inner side. According to this configuration, the end part of the case 80 on the opening side of the opening portion 80D can be sandwiched by the side flange portions 16E and the second side flange portions 16D. As a result, a concave-convex structure can be realized by arranging the end part on the opening side of the opening portion 80D between the side flange portions 16E and the second side flange portions 16D.

The side surface 22C of the receptacle 16 includes the press-fit portions 27, into which the fixing member 12 for fixing the receptacle 16 to the circuit board 90 is press-fit, and the front ends of the press-fit portions 27 are integrally coupled to the second flange portion 16B. According to this configuration, since the press-fit portions 27 are reinforced by the second flange portion 16B, the fixing members 12 can be properly held. Further, since the second flange portion 16B is reinforced by the press-fit portions 27, the deformation of the second flange portion 16B due to contact with the case 80 can be prevented.

The front wall 80C of the case 80 is in contact with the front surface of the second flange portion 16B. According to this configuration, the intrusion of an external matter into the case 80 can be more reliably prevented.

### Other Embodiments of Present Disclosure

The present disclosure is not limited to the above described and illustrated embodiment. The present invention is intended to include all changes in the scope of claims and in the meaning and scope of equivalents and also include the following embodiments.

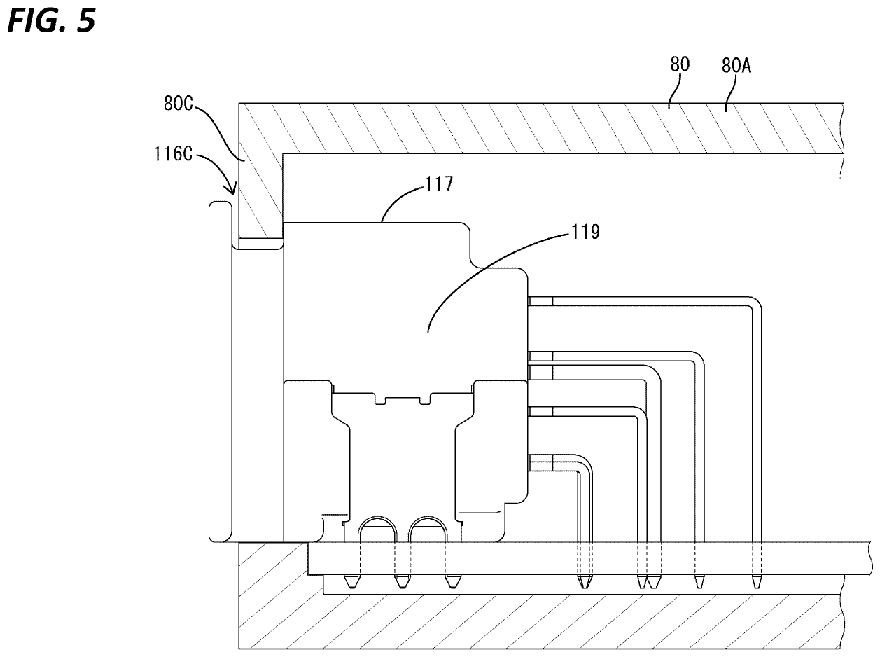

(1) Unlike the above embodiment, a groove portion 116C may be formed to be recessed inward by increasing thicknesses of an upper wall 117 and a pair of side walls 119 as shown in FIG. 5. In this case, the thickened upper wall 117 and pair of side walls 119 are equivalent to the facing portion.

(2) Unlike the above embodiment, the flange portion and the second flange portion may be formed also on the mounting surface. That is, the flange portion and the second flange portion may be formed over the four surfaces of the outer periphery of the receptacle.

(3) Unlike the above embodiment, the front wall of the case may contact the back surface of the flange portion. Further, the front wall of the case may contact the back surface of the flange portion and the front surface of the second flange portion.

(4) Unlike the above embodiment, the dimension between the mounting surface and the surface of the circuit board may be set to be less than 1.0 mm.

### LIST OF REFERENCE NUMERALS

10 . . . connector
11 . . . housing
12 . . . fixing member
13 . . . terminal fitting
13A . . . tab
15 . . . wall portion
16 . . . receptacle
16A . . . flange portion
16B . . . second flange portion (facing portion)
16C, 116C . . . groove portion
16D . . . second side flange portion
16E . . . side flange portion
17, 117 . . . upper wall
18 . . . lower wall
19, 119 . . . side wall
22A . . . end surface
22B . . . mounting surface
22C . . . side surface
24 . . . inner wall
26 . . . through hole
27 . . . press-fit portion
28 . . . groove
33 . . . housing mounting portion
34 . . . board fixing portion
80 . . . case
80A . . . upper case
80B . . . lower case
80C . . . front wall
80D . . . opening
80E . . . rib
90 . . . circuit board
90A . . . surface 90B . . . underside
P . . . mating connector

1. A connector, comprising a receptacle, a mating connector being fittable into the receptacle,
if an opening side of the receptacle is a front side and a side opposite to the opening side is a back side, the receptacle including:
a flange portion formed into a flange shape on an outer periphery of an end edge on the front side;
a facing portion arranged to face the flange portion from the back side; and
a groove portion formed between the facing portion and the flange portion, a plate-like case being fit into the groove portion.

2. The connector of claim 1, wherein the facing portion is a second flange portion formed into a flange shape behind the end edge on the front side on the outer periphery of the receptacle.

3. The connector of claim 2, wherein:
one surface of the receptacle is a mounting surface to be mounted on a circuit board, out of four surfaces of the outer periphery having a rectangular tube shape, and
the flange portion and the second flange portion are formed over three surfaces including a pair of side surfaces and an end surface located on a side opposite to the mounting surface except the mounting surface, out of the four surfaces of the outer periphery.

4. The connector of claim 3, wherein:
the flange portion and the second flange portion include side flange portions and second side flange portions on the respective side surfaces, and
the side flange portions and the second side flange portions are shaped to increase an outward projecting amount from the side surface from the end surface side toward the mounting surface side.

5. The connector of claim 3, wherein:
the side surface of the receptacle includes a press-fit portion, a fixing member for fixing the receptacle to the circuit board being press-fit into the press-fit portion, and
a front end of the press-fit portion is integrally coupled to the second flange portion.

6. The connector of claim 2, wherein the case is in contact with at least one of a back surface of the flange portion and a front surface of the second flange portion.

7. The connector of claim 5, wherein the case is in contact with at least one of a back surface of the flange portion and a front surface of the second flange portion.
